(19) United States
(12) Patent Application Publication
(10) Pub. No.: US 2022/0386502 A1
(43) Pub. Date: Dec. 1, 2022

(54) GAS STORAGE DEVICE AND TWO-PHASE IMMERSION COOLING SYSTEM

(71) Applicants: Inventec (Pudong) Technology Corp., Shanghai (CN); Inventec Corporation, Taipei (TW)

(72) Inventors: Kai-Yang Tung, Taipei (TW); Hung-Ju Chen, Taipei (TW)

(21) Appl. No.: 17/342,503

(22) Filed: Jun. 8, 2021

(30) Foreign Application Priority Data
May 25, 2021 (CN) 202110572611.3

(51) Int. Cl. H05K 7/20; F28F 27/00

(52) U.S. Cl. CPC H05K 7/203; H05K 7/20327; F28F 27/00; F28F 2265/12

(57) ABSTRACT

A gas storage device includes a casing, a lift platform, a lift mechanism, a driving mechanism, an exhaust valve and a gas joint. The lift platform is movably disposed in the casing, wherein a gas storage space is between a bottom of the casing and the lift platform. The lift mechanism is disposed in the casing and connected to the lift platform. The driving mechanism is connected to the lift mechanism. The driving mechanism drives the lift mechanism to drive the lift platform to move. The exhaust valve is connected to the lift platform and communicates with the gas storage space. The gas joint is connected to the bottom of the casing and communicates with the gas storage space.

### BACKGROUND OF THE INVENTION

### 1. Field of the Invention

The invention relates to a gas storage device and a two-phase immersion cooling system and, more particularly, to a gas storage device with pressure adjusting function and a two-phase immersion cooling system equipped with the gas storage device.

### 2. Description of the Prior Art

A two-phase immersion cooling system uses dielectric liquid to dissipate heat from electronic components by a phase change manner. The two-phase immersion cooling system usually has a gas storage device for temporarily containing excess vapor of the dielectric liquid. In general, the gas in the cooling system can only passively flow through the pressure difference between a cooling tank and the gas storage device (or the outside). Therefore, when the pressure in the cooling tank is larger than the outside pressure, the cooling system can only reduce the pressure in the cooling tank to be close to the outside pressure by opening an exhaust valve or a tube connected with the gas storage device. The pressure in the cooling tank cannot be further reduced, such that the vapor of the dielectric liquid in the cooling tank may leak out.

### SUMMARY OF THE INVENTION

The invention provides a gas storage device with pressure adjusting function and a two-phase immersion cooling system equipped with the gas storage device, so as to solve the aforesaid problems.

According to an embodiment of the invention, a gas storage device comprises a casing, a lift platform, a lift mechanism, a driving mechanism, an exhaust valve and a gas joint. The lift platform is movably disposed in the casing, wherein a gas storage space is between a bottom of the casing and the lift platform. The lift mechanism is disposed in the casing and connected to the lift platform. The driving mechanism is connected to the lift mechanism. The driving mechanism drives the lift mechanism to drive the lift platform to move. The exhaust valve is connected to the lift platform and communicates with the gas storage space. The gas joint is connected to the bottom of the casing and communicates with the gas storage space.

According to an embodiment of the invention, a two-phase immersion cooling system comprises a gas storage device and a cooling tank. The gas storage device comprises a casing, a lift platform, a lift mechanism, a driving mechanism, an exhaust valve and a gas joint. The lift platform is movably disposed in the casing, wherein a gas storage space is between a bottom of the casing and the lift platform. The lift mechanism is disposed in the casing and connected to the lift platform. The driving mechanism is connected to the lift mechanism. The driving mechanism drives the lift mechanism to drive the lift platform to move. The exhaust valve is connected to the lift platform and communicates with the gas storage space. The gas joint is connected to the bottom of the casing and communicates with the gas storage space. The cooling tank is connected to the gas joint.

As mentioned in the above, the gas storage device of the invention controls the lift platform to move by the driving mechanism and the lift mechanism and controls the exhaust valve and the gas joint to open or close, such that the gas flows into or out of the cooling tank to control the pressure in the cooling tank. Since the movement of the lift platform is driven by the driving mechanism, the invention can reduce the pressure in the cooling tank no matter whether the pressure in the cooling tank is larger than the outside pressure. By compressing the cooling tank with a large outside pressure to reduce the gap, the invention can prevent the vapor of the dielectric liquid in the cooling tank from leaking out. Needless to say, the invention can also increase the pressure in the cooling tank to normal or specific pressure according to practical applications.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a perspective view illustrating a gas storage device according to an embodiment of the invention.

FIG. 2 is an exploded view illustrating a gas storage device shown in FIG. 1.

FIG. 3 is a sectional view illustrating a two-phase immersion cooling system equipped with the gas storage device shown in FIG. 1.

FIG. 4 is a sectional view illustrating a lift platform shown in FIG. 3 moving upward.

FIG. 5 is a sectional view illustrating the lift platform shown in FIG. 3 moving downward.

### DETAILED DESCRIPTION

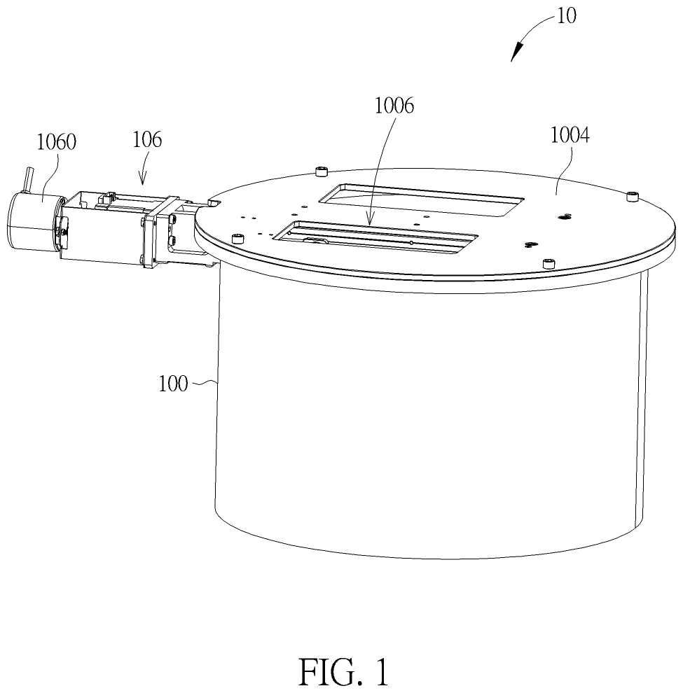

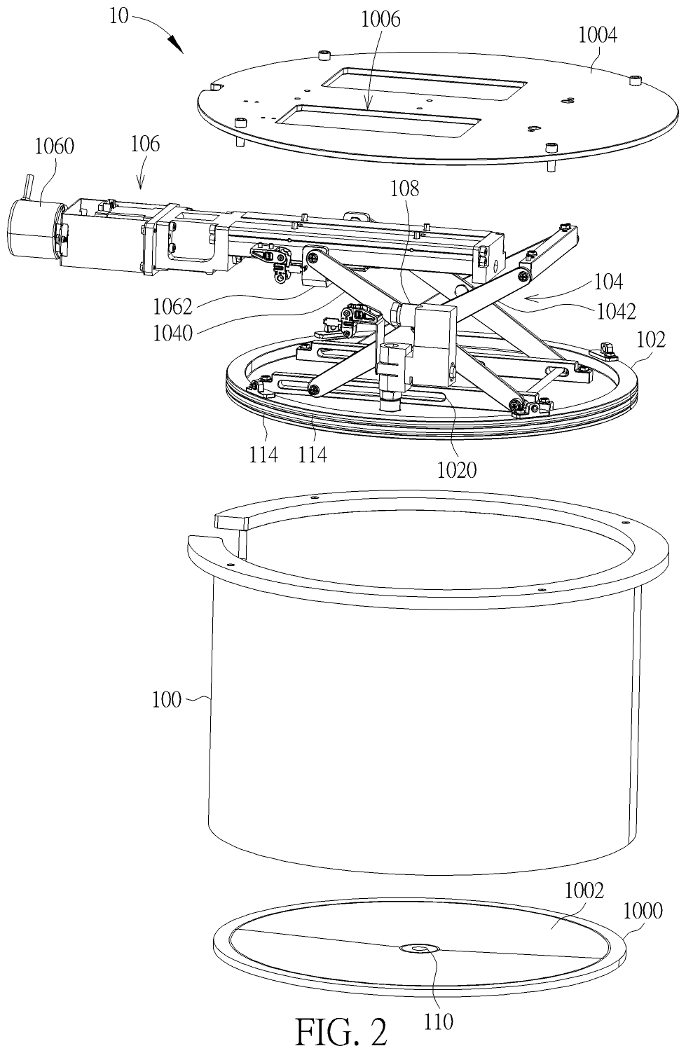

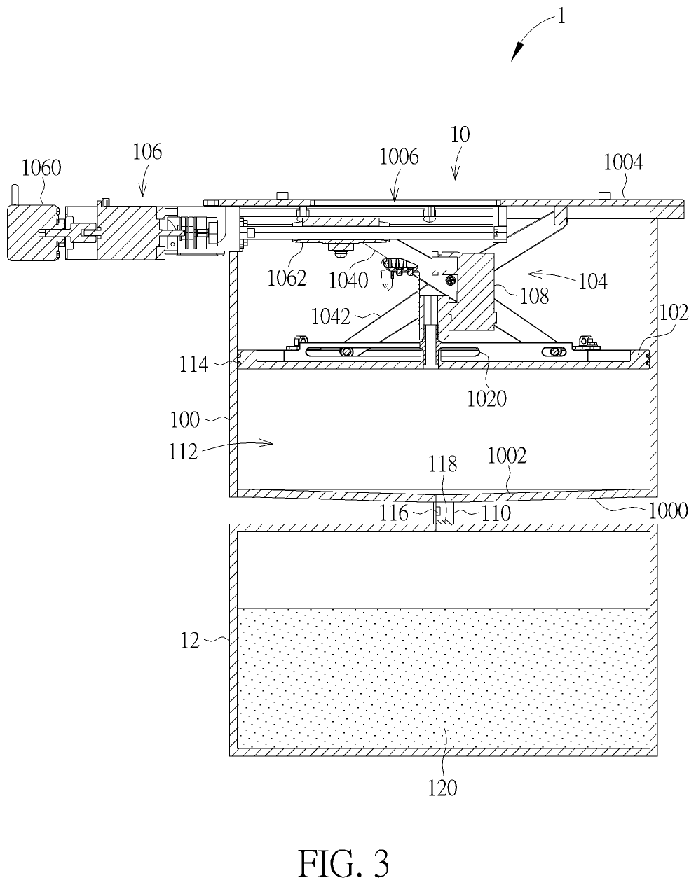

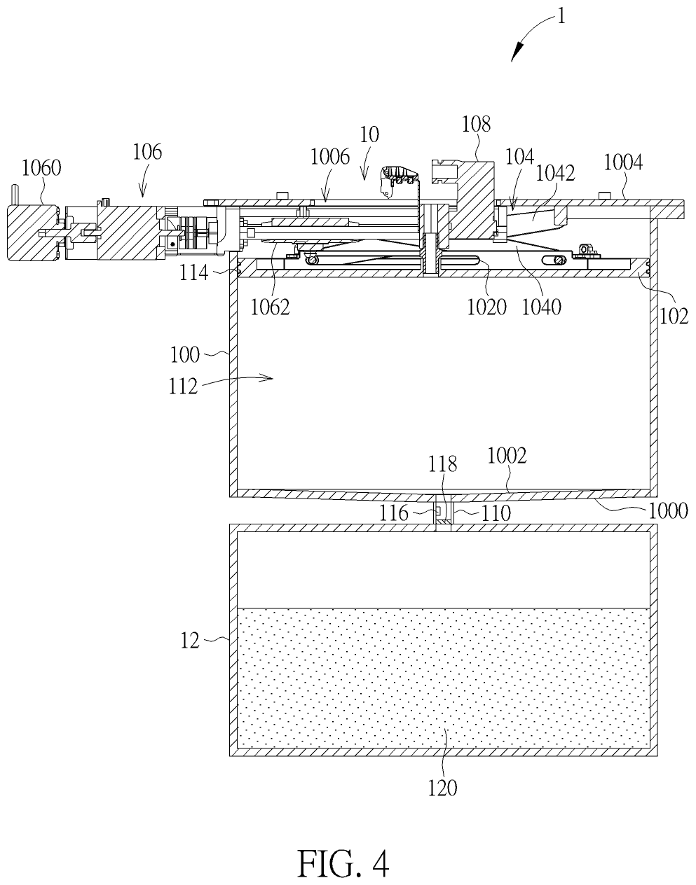

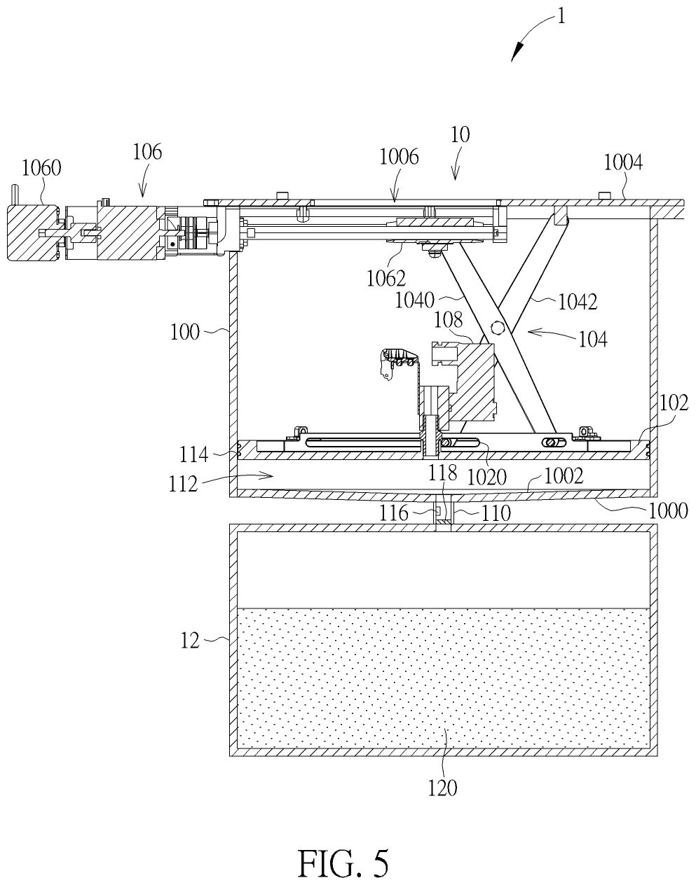

Referring to FIGS. 1 to 5, FIG. 1 is a perspective view illustrating a gas storage device 10 according to an embodiment of the invention, FIG. 2 is an exploded view illustrating a gas storage device 10 shown in FIG. 1, FIG. 3 is a sectional view illustrating a two-phase immersion cooling system 1 equipped with the gas storage device 10 shown in FIG. 1, FIG. 4 is a sectional view illustrating a lift platform 102 shown in FIG. 3 moving upward, and FIG. 5 is a sectional view illustrating the lift platform 102 shown in FIG. 3 moving downward.

As shown in FIGS. 1 to 3, the gas storage device 10 comprises a casing 100, a lift platform 102, a lift mechanism 104, a driving mechanism 106, an exhaust valve 108 and a gas joint 110. The lift platform 102 is movably disposed in the casing 100, wherein a gas storage space 112 is between a bottom 1000 of the casing 100 and the lift platform 102. The lift mechanism 104 is disposed in the casing 100 and connected to the lift platform 102. The driving mechanism 106 is connected to the lift mechanism 104. The driving mechanism 106 is used to drive the lift mechanism. 104 to drive the lift platform 102 to move upward and downward. The exhaust valve 108 is connected to the lift platform 102 and communicates with the gas storage space 112. The gas joint 110 is connected to the bottom 1000 of the casing 100 and communicates with the gas storage space 112.

As shown in FIG. 3, the two-phase immersion cooling system 1 comprises the aforesaid gas storage device 10 and a cooling tank 12. The cooling tank 12 is connected to the gas joint 110 of the gas storage device 10. The cooling tank 12 stores a dielectric liquid 120 with a low boiling point. An electronic component (not shown) may be immersed in the dielectric liquid 120. The dielectric liquid 120 evaporates into vapor after absorbing the heat generated by the electronic component. The vapor will flow into the casing 100 of the gas storage device 10 through the gas joint 110 to be stored in the gas storage space 112.

In this embodiment, the gas storage device 10 may further comprise a sealing gasket 114 sleeved on a periphery of the lift platform 102 and abutting against an inner wall of the casing 100. The sealing gasket 114 can prevent the vapor from leaking to the outside and prevent the outside gas from flowing into the gas storage space 112. In this embodiment, there are two sealing gaskets 114 sleeved on the periphery of the lift platform 102, but the invention is not so limited. The number of the sealing gaskets 114 may be determined according to practical applications. The sealing gasket 114 may be an O-ring or the like.

In this embodiment, the gas storage device 10 may further comprise a cooling device 116 disposed in the gas joint 110. The cooling device 116 may reduce the temperature of the vapor passing through the gas joint 110, such that the vapor condenses into the dielectric liquid and then flows back to the cooling tank 12 for recycling. Accordingly, the invention may reduce the leakage of the vapor of the dielectric liquid. Furthermore, the bottom 1000 of the casing 100 may have an inclined surface 1002, wherein the inclined surface 1002 is inclined toward the gas joint 110. After the vapor of the dielectric liquid condenses into liquid in the gas storage space 112, the liquid flows back to the cooling tank 12 along the inclined surface 1002.

In this embodiment, the gas storage device 10 may further comprise a gas inlet valve 118 connected to the gas joint 110. The gas inlet valve 118 is served as a switch of the gas joint 110.

In this embodiment, the driving mechanism 106 may comprise a motor 1060 and a movable member 1062. The motor 1060 is connected to the movable member 1062 and the movable member 1062 is connected to the lift mechanism 104. The motor 1060 is used to drive the movable member 1062 to move forward and backward, such that the movable member 1062 drives the lift mechanism 104 to drive the lift platform 102 to move upward and downward.

In this embodiment, the lift mechanism, 104 may be a scissor-type linkage assembly. For further illustration, the lift mechanism 104 may comprise a first support member 1040 and a second support member 1042. Furthermore, the lift platform. 102 has a sliding groove 1020. The first support member 1040 is pivotally connected to the second support member 1042. Two ends of the first support member 1040 are pivotally connected to the movable member 1062 and the lift platform. 102. Two ends of the second support member 1042 are pivotally connected to a top 1004 of the casing 100 and the sliding groove 1020 of the lift platform 102. Accordingly, when the motor 1060 drives the movable member 1062 to move forward and backward, the movable member 1062 drives the lift mechanism 104 to drive the lift platform 102 to move upward and downward.

The invention may reduce the pressure in the cooling tank 12 to specific pressure, even lower than the outside pressure, by the operation of the gas storage device 10. First, the gas inlet valve 118 is opened, the exhaust valve 108 is closed, and the driving mechanism 106 is controlled to drive the lift mechanism 104 to drive the lift platform 102 to move upward (as shown in FIG. 4), such that the gas in the cooling tank 12 flows into the gas storage space 112. In this embodiment, the top 1004 of the casing 100 has an opening 1006, wherein a position of the opening 1006 corresponds to a position of the exhaust valve 108. As shown in FIG. 4, after the lift platform 102 moves upward, the exhaust valve 108 passes through the opening 1006, so as to prevent the exhaust valve 108 from interfering with the top 1004 of the casing 100. Then, the gas inlet valve 118 is closed, the exhaust valve 108 is opened, and the driving mechanism 106 is controlled to drive the lift mechanism 104 to drive the lift platform 102 to move downward (as shown in FIG. 5), such that the gas in the gas storage space 112 is exhausted out of the casing 100. Then, the aforesaid steps are repeated until the pressure in the cooling tank 12 is lower than the outside pressure. By compressing the cooling tank 12 with a large outside pressure to reduce the gap, the invention can prevent the vapor of the dielectric liquid in the cooling tank 12 from leaking out.

When it is necessary to increase the pressure in the cooling tank to normal pressure, the gas inlet valve 118 is opened and the driving mechanism 106 is controlled to drive the lift mechanism 104 to drive the lift platform 102 to move downward, such that the gas in the gas storage space 112 flows into the cooling tank 12. If more gas needs to be added, the exhaust valve 108 can be opened to introduce the outside gas into the gas storage space 112, such that the inside and outside pressures of the cooling tank 12 are balanced.

If it is necessary to increase the pressure in the cooling tank 12 to specific pressure, the exhaust valve 108 is opened, the gas inlet valve 118 is closed, and the driving mechanism 106 is controlled to drive the lift mechanism 104 to drive the lift platform 102 to move upward, so as to suck the outside gas into the gas storage space 112. Then, the exhaust valve 108 is closed, the gas inlet valve 118 is opened, and the driving mechanism 106 is controlled to drive the lift mechanism 104 to drive the lift platform 102 to move downward, so as to inject the gas in the gas storage space 112 into the cooling tank 12. Then, the aforesaid steps are repeated until the pressure in the cooling tank 12 increases to specific pressure.

As mentioned in the above, the gas storage device of the invention controls the lift platform to move by the driving mechanism and the lift mechanism and controls the exhaust valve and the gas joint to open or close, such that the gas flows into or out of the cooling tank to control the pressure in the cooling tank. Since the movement of the lift platform is driven by the driving mechanism, the invention can reduce the pressure in the cooling tank no matter whether the pressure in the cooling tank is larger than the outside pressure. By compressing the cooling tank with a large outside pressure to reduce the gap, the invention can prevent the vapor of the dielectric liquid in the cooling tank from leaking out. Needless to say, the invention can also increase the pressure in the cooling tank to normal or specific pressure according to practical applications.

In an embodiment of the invention, the two-phase immersion cooling system of the invention may be applied to a server, wherein the server may not only be applied to artificial intelligence (AI) and edge computing, but also be used as a 5G server, a cloud server or an Internet of Vehicles server.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A gas storage device comprising:
a casing;
a lift platform movably disposed in the casing, a gas storage space being between a bottom of the casing and the lift platform;
a lift mechanism disposed in the casing and connected to the lift platform;
a driving mechanism connected to the lift mechanism, the driving mechanism driving the lift mechanism to drive the lift platform to move;
an exhaust valve connected to the lift platform and communicating with the gas storage space; and
a gas joint connected to the bottom of the casing and communicating with the gas storage space.

2. The gas storage device of claim 1, further comprising a sealing gasket sleeved on a periphery of the lift platform and abutting against an inner wall of the casing.

3. The gas storage device of claim 1, wherein a top of the casing has an opening and a position of the opening corresponds to a position of the exhaust valve.

4. The gas storage device of claim 1, wherein the bottom of the casing has an inclined surface inclined toward the gas joint.

5. The gas storage device of claim 1, further comprising a cooling device disposed in the gas joint.

6. The gas storage device of claim 1, wherein the driving mechanism comprises a motor and a movable member, the motor is connected to the movable member, the movable member is connected to the lift mechanism, the motor drives the movable member to move, such that the movable member drives the lift mechanism to drive the lift platform to move.

7. The gas storage device of claim 6, wherein the lift mechanism comprises a first support member and a second support member, the lift platform has a sliding groove, the first support member is pivotally connected to the second support member, two ends of the first support member are pivotally connected to the movable member and the lift platform, two ends of the second support member are pivotally connected to a top of the casing and the sliding groove.

8. The gas storage device of claim 1, wherein the lift mechanism is a scissor-type linkage assembly.

9. The gas storage device of claim 1, further comprising a gas inlet valve connected to the gas joint.

10. A two-phase immersion cooling system comprising:
a gas storage device comprising:
a casing;
a lift platform movably disposed in the casing, a gas storage space being between a bottom of the casing and the lift platform;
a lift mechanism disposed in the casing and connected to the lift platform;
a driving mechanism connected to the lift mechanism, the driving mechanism driving the lift mechanism to drive the lift platform to move;
an exhaust valve connected to the lift platform and communicating with the gas storage space; and
a gas joint connected to the bottom of the casing and communicating with the gas storage space; and
a cooling tank connected to the gas joint.

11. The two-phase immersion cooling system of claim 10, wherein the gas storage device further comprises a sealing gasket sleeved on a periphery of the lift platform and abutting against an inner wall of the casing.

12. The two-phase immersion cooling system of claim 10, wherein a top of the casing has an opening and a position of the opening corresponds to a position of the exhaust valve.

13. The two-phase immersion cooling system of claim 10, wherein the bottom of the casing has an inclined surface inclined toward the gas joint.

14. The two-phase immersion cooling system of claim 10, wherein the gas storage device further comprises a cooling device disposed in the gas joint.

15. The two-phase immersion cooling system of claim 10, wherein the driving mechanism comprises a motor and a movable member, the motor is connected to the movable member, the movable member is connected to the lift mechanism, the motor drives the movable member to move, such that the movable member drives the lift mechanism to drive the lift platform to move.

16. The two-phase immersion cooling system of claim 15, wherein the lift mechanism comprises a first support member and a second support member, the lift platform has a sliding groove, the first support member is pivotally connected to the second support member, two ends of the first support member are pivotally connected to the movable member and the lift platform, two ends of the second support member are pivotally connected to a top of the casing and the sliding groove.

17. The two-phase immersion cooling system of claim 10, wherein the lift mechanism is a scissor-type linkage assembly.

18. The two-phase immersion cooling system of claim 10, wherein the gas storage device further comprises a gas inlet valve connected to the gas joint.
